(19) United States
(12) Patent Application Publication
(10) Pub. No.: US 2009/0305481 A1
(43) Pub. Date: Dec. 10, 2009

(54) METHOD FOR MANUFACTURING SEMICONDUCTOR MEMORY DEVICE

(76) Inventor: Ji Ho Hong, Hwaseong-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/474,696

(22) Filed: May 29, 2009

(30) Foreign Application Priority Data
Jun. 5, 2008 (KR) 10-2008-0052951

(51) Int. Cl. H01L 21/762; G03F 7/20

(52) U.S. Cl. 438/424; 430/319; 257/E21.546; 438/795

(57) ABSTRACT

Disclosed are methods for manufacturing a semiconductor memory device. According to an embodiment, a method includes forming a trench to form an isolation layer performing an annealing process to reduce an amount of a leakage current in an active layer, and performing a gap-fill process with respect to the trench. Another method in accordance with an embodiment includes performing a lithography process to form an active layer, in which a line critical dimension (CD) in the active layer is increased by about 3 nm to about 6 nm as compared with a line CD in a Process of Record (POR).

### CROSS-REFERENCE TO RELATED APPLICATION

The present application claims the benefit under 35 U.S.C. §119 of Korean Patent Application No. 10-2008-0052951, filed Jun. 5, 2008, which is hereby incorporated by reference in its entirety.

### BACKGROUND

Stress on an active layer is an important factor for characteristics of a semiconductor device. In particular, the stress applied to the active layer exerts a significant influence upon driving current and leakage current characteristics of the semiconductor device. As the semiconductor device becomes highly integrated, semiconductor layers such as the active layer are scaled down and the stress applied to the active layer is increased.

For example, as the NOR flash device is further integrated, the number of bit cells included in one bit line is increased, and the size of the bit cell (i.e., the pattern size of an active layer, a floating gate, and a control gate, which constitute one flash device) is scaled down. Thus, a bit line leakage current increases.

For example, in the case of a flash device having a tech node of about 90 nm, which serves as a criterion for integration, one bit line has about 512 bit cells and one word line has about 2048 bit cells.

In such a case, one device sector has a capacity of about IM (512×2048) bit, and a memory device with a capacity of 128M has 128 device sectors.

Therefore, the amount of the bit line leakage current may be defined as the sum of the drain current of about 512 erased-bit cells, which may be regarded as a bit cell leakage current. Under the conditions in which a drain voltage is 0.7 μV, a gate voltage is 0 μV, and source and bulk voltages are equal to a ground voltage, the bit line leakage current must be equal to or less than 5 μV.

Further, the bit line leakage current, which is measured from the 2048 word lines crossing the bit lines, must be equal to or less than 5 μA. However, the bit line leakage current may not satisfy the above condition of 5 μA due to various process conditions, the size of the active layer, device location on a wafer, and stress factors, and may be irregularly generated from the bit lines.

FIG. 1 is a plan view schematically showing a structure of a memory device, FIGS. 2A and 2B are plan views showing arrangements of various memory devices, and FIG. 3 is a graph schematically showing drain current characteristics of PMOS and NMOS transistors in a single gate device.

In the case of the single gate device shown in FIG. 1 and FIG. 2B, if the sizes d1 and d2 of active layers formed at both sides of a poly gate are enlarged, the amount of drain current changes in accordance with the plot as shown in FIG. 3.

Referring to FIG. 3, the X axis denotes size of the active layer and the Y axis denotes variation (%) of the drain current. The size (or area) of the active area is simplified here as a function of width (e.g, μm) based on a constant length. In the case of the NMOS transistor, electrons increase proportionally to the area of the active layer resulting in the drain current curve as expressed by line “A” of FIG. 3. In the case of the PMOS transistor, holes increase proportionally to the area of the active layer resulting in the drain current as expressed by line “B” of FIG. 3. Line “C” represents no variation of the drain current when the bit cell has been erased, and line “D” represents a modeling reference point for the area of the active layer.

In the case of a multi-finger gate device such as shown in FIG. 2A, the size “d4” of the active layer at one side of a poly gate is larger than the size “d3” of the active layer at the other side of the poly gate, and a result contrary to the result of FIG. 3 may be obtained by a measurement test.

Accordingly, in both the case of a single gate device and the case of the multi-finger gate device, the irregularity of a leakage current in bit lines occur

### BRIEF SUMMARY

Methods for manufacturing a semiconductor memory device are provided, capable of minimizing a bit line leakage current regardless of various process conditions, device integration, device location on a wafer, and stress factors. Embodiments are provided, capable of minimizing the irregularity of a leakage current in bit lines.

According to an embodiment, a method for manufacturing a semiconductor memory device can include forming a trench for an isolation layer, performing an annealing process to reduce an amount of a leakage current in an active layer, and performing a gap-fill process with respect to the trench. The annealing process can be performed before performing the gap-fill process with respect to the trench.

According to another embodiment, a method for manufacturing a semiconductor memory device can include performing a lithography process to form an active layer, in which a line critical dimension (CD) of the active layer is increased by about 3 nm to about 6 nm as compared with a line CD in a Process of Record (POR).

### BRIEF DESCRIPTION OF THE DRAWINGS

FIG. 1 is a plan view schematically showing the structure of a memory device;

FIGS. 2A and 2B are plan views showing arrangement of various memory devices;

FIG. 3 is a graph schematically showing drain current characteristics of PMOS and NMOS transistors for the case of a single gate device;

FIG. 4 is a side sectional view schematically showing the structure of a semiconductor memory device manufactured through a method for manufacturing a semiconductor device according to a first embodiment;

FIGS. 5A and 5B are graphs showing an amount of a bit line leakage current in a conventional semiconductor memory device and the semiconductor memory device manufactured through the method according to the first embodiment, respectively;

FIG. 6 is a view schematically showing a line critical dimension in a semiconductor memory device manufactured through a method for manufacturing a semiconductor memory device according to a second embodiment and a semiconductor memory device manufactured according to a POR; and

FIGS. 7A and 7B are graphs showing an amount of a bit line leakage current in the semiconductor memory device manufactured through the method according to the second embodiment and the semiconductor memory device manufactured according to the POR, respectively.

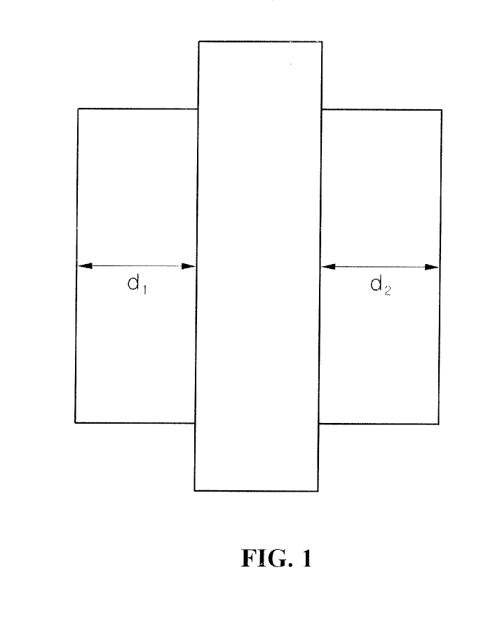

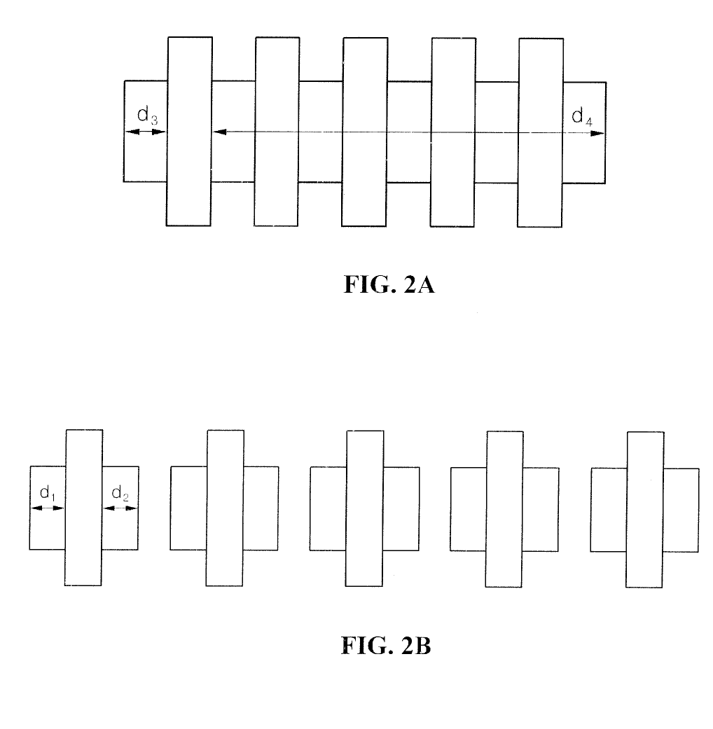

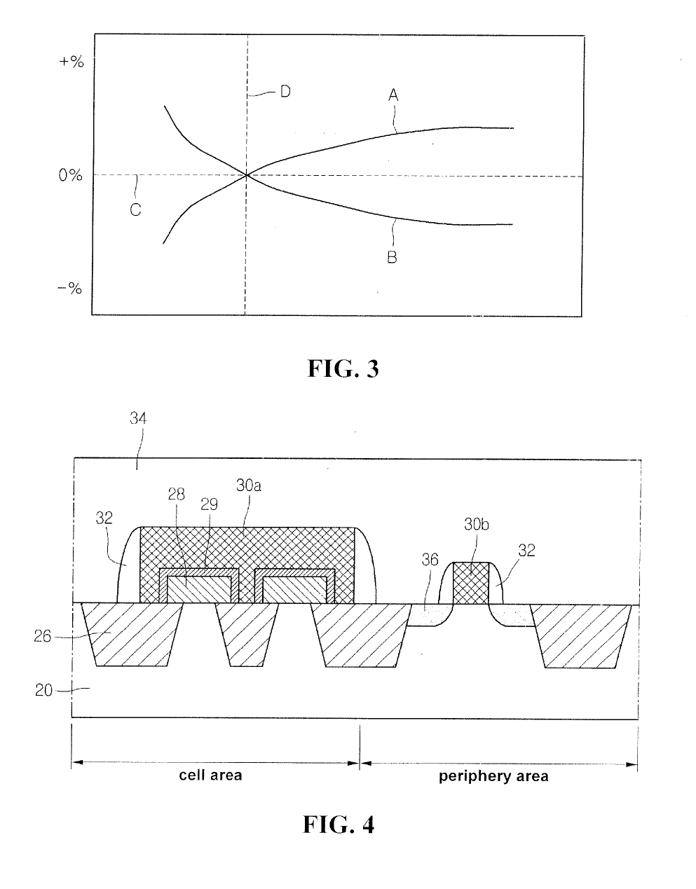

### DETAILED DESCRIPTION

Hereinafter, methods for manufacturing a semiconductor memory device according to embodiments will be described in detail with reference to accompanying drawings.

Detailed description about well known functions or configurations may make the subject matter of the disclosure unclear. Accordingly, hereinafter, description will be made regarding only essential components directly related to the technical spirit of the disclosure.

In the following description, the semiconductor memory device according to embodiments is employed as a NOR flash memory device.

Hereinafter, a method for manufacturing a semiconductor memory device according to the embodiments will be described.

FIG. 4 is a side sectional view schematically showing a structure of a semiconductor memory device manufactured through a method for manufacturing a semiconductor device according to a first embodiment.

The semiconductor memory device can have a cell area and a periphery area, where data write and erase operations are performed in the cell area and a transistor is operated in the periphery area corresponding to the data write and erase operations.

First, after forming a photoresist pattern (not shown) to define an area for an isolation layer on a semiconductor substrate 20, a trench can be formed through an etch process.

Thereafter, a wet etch process can be performed to remove the photoresist pattern, and then an annealing process is performed with respect to the resultant structure.

The annealing process can be performed by using a nitrogen (N₂) gas under a temperature of about 1100° C. or about 1200° C. for about 5 minutes to about 15 minutes.

After the annealing process is finished, an insulating layer can be formed on the semiconductor substrate 20 such that the insulating layer fills in the trench.

Subsequently, the insulating layer is planarized such that the semiconductor substrate 20 is exposed, thereby forming an isolation layer 26 within the trench.

As described above, according to the first embodiment, the annealing process is performed before a gap-fill process of the trench is performed, so that a well layer and an active layer formed during subsequent processes represent strong resistance against stress. In other words, an amount of a bit line leakage current of the semiconductor device can be minimized if the annealing process is performed under the predetermined conditions in accordance with the first embodiment.

According to embodiments, an additional annealing process is not performed for the isolation layer 26 after the planarization process. By not performing an annealing process after forming the isolation layer, the stress resistance created by the annealing process performed in accordance with the first embodiment can be maintained as much as possible.

The isolation layer 26 insulates various devices, which are formed on the semiconductor substrate 20 through subsequent processes, from each other.

In one embodiment, the subsequent processes can be as follows:

After forming the isolation layer 26, an oxide layer may be formed on the semiconductor substrate 20. The oxide layer may be formed as a gate oxide layer in a gate area.

Thereafter, an ion implantation process can be performed with respect to the semiconductor substrate 20 including the isolation layer 26, so that P and N wells (not shown) are formed in the semiconductor substrate 20.

After the P well and the N well have been formed, a first polysilicon layer is formed and patterned on the semiconductor substrate 20, thereby forming a first polysilicon layer pattern 28 in the cell area. The first polysilicon layer pattern 28 can serve as a floating gate. The first polysilicon layer pattern 28 can be formed of doped polysilicon.

Thereafter, an oxide layer, a nitride layer, and an oxide layer can be sequentially formed on the semiconductor substrate 20 including the first polysilicon layer pattern 28, and annealing and patterning are performed with respect to the resultant structure, thereby forming an ONO layer 29 on the first polysilicon layer 28 in the cell area.

The ONO layer 29 insulates an upper portion of a device on the semiconductor substrate 20 from a lower portion thereof. The first polysilicon layer pattern 28 can be surrounded by the ONO layer 29. Accordingly, since the first polysilicon layer pattern 28 is doped with a doping material, charges (or electrons) exist in an excited state inside the first polysilicon layer pattern 28.

A second polysilicon layer can be formed on the semiconductor substrate 20 including the ONO layer 29. Then, the resultant structure is patterned, thereby forming second polysilicon layer patterns 30a and 30b in the cell area and the periphery area, respectively. The second polysilicon layer pattern 30a formed in the cell area serves as a control gate, and the second polysilicon layer pattern 30b formed in the periphery area serves as a floating gate.

The second polysilicon layer pattern 30a of the cell area covers the ONO layer 29, and the second polysilicon layer of the periphery area is directly patterned and formed on the semiconductor substrate 20 having a gate oxide layer (not shown).

The second polysilicon layer pattern 30a of the cell area can be used to apply a bias voltage so as to charge or discharge electrons existing in the first polysilicon layer pattern 28 by exciting the electrons.

After the first polysilicon layer pattern 28 and the second polysilicon layer patterns 30a and 30b have been formed, spacers 32 can be formed at sides of the second polysilicon layer patterns 30a and 30b. Then, an ion implantation process is performed by using the spacers 32 and the second polysilicon layer patterns 30a and 30b as a mask, thereby forming an active layer, that is, a source/drain area 36 on the semiconductor substrate 20.

Thereafter, an inter-layer insulating layer 34 can be formed on the semiconductor substrate 20 including the source/drain area 36 using, for example, undoped silica glass (USG) or boron phosphorus silicate glass (BPSG).

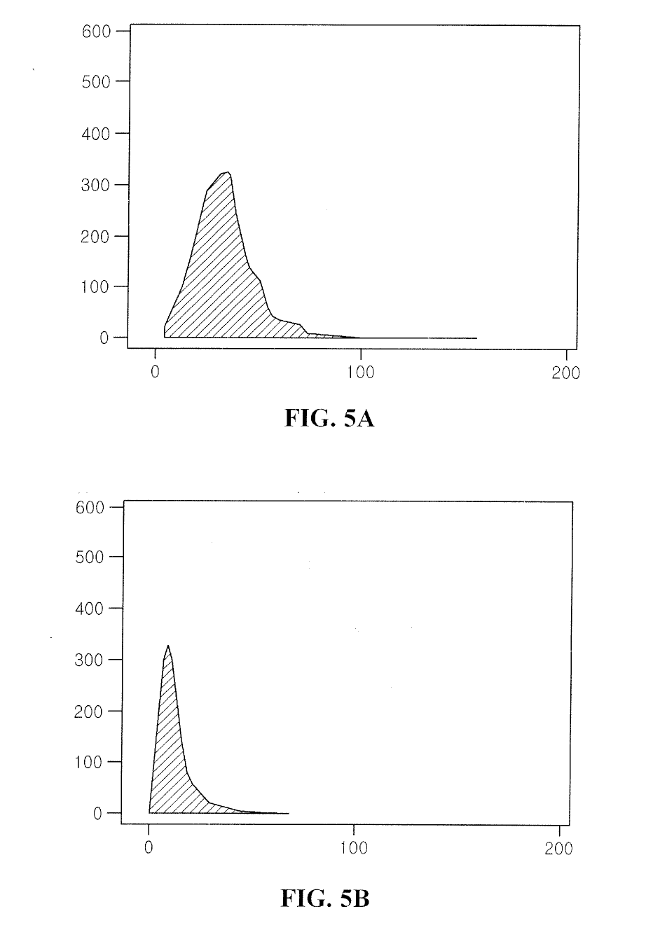

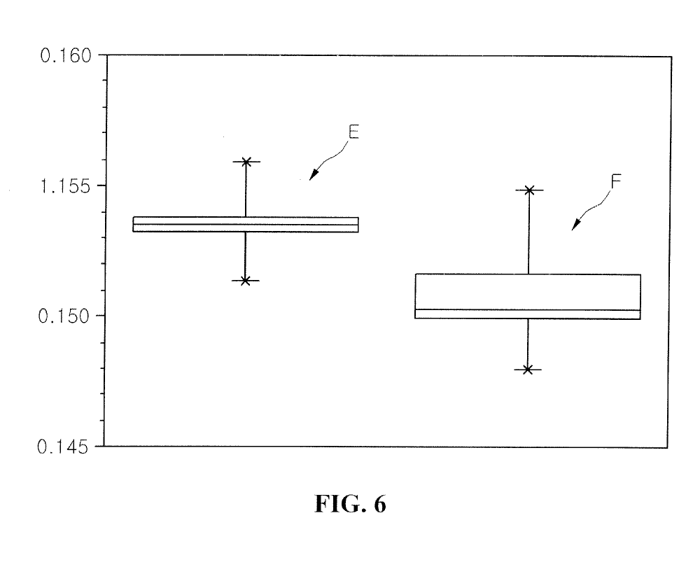

FIGS. 5A and 5B are graphs showing an amount of a bit line leakage current in the semiconductor memory devices manufactured through the method according to the first embodiment and a conventional semiconductor device.

For reference, 90 nm NOR flash memory products are employed as the semiconductor memory devices of FIGS. 5A and 5B.

FIG. 5A is a graph representing the measured result of a bit line leakage current of a semiconductor memory device manufactured according to a Process of Record (POR), and FIG. 5B is a graph representing the measured result of a bit line leakage current of the semiconductor memory device manufactured the method according to the first embodiment.

For reference, the POR represents the combination of unit processes in which process conditions are optimized according to device design criteria that have been currently used. In the POR, a voltage has been applied so as to erase data from bit cells before a leakage current is measured.

In the graphs of FIGS. 5A and 5B, the X and Y axes represent an amount (μA) of the bit line leakage current and the number of bit lines, respectively.

As shown in FIG. 5A, an average amount of the bit line leakage current is about 33.8 μA, and the maximum amount of the bit line leakage current is about 155 μA.

As shown in FIG. 5B, an average amount of the bit line leakage current is about 11.3 μA, and the maximum amount of the bit line leakage current is about 65 μA.

As described above, according to the method for manufacturing the semiconductor memory device of the first embodiment, the bit line leakage current is reduced to the level of ⅓ when comparing with the bit line leakage current according to the conventional POR. This means that the stress resistance of a device is significantly improved in each semiconductor area, especially, the active layer.

In addition, although about 52 ms are taken to check data erase of bit cells in the case of the graph show in FIG. 5A, about 38 ms are taken to check data erase of bit cells in the case of the graph shown in FIG. 5B according to the embodiment.

This is because the bit line leakage current can be significantly reduced. Accordingly, since test time can be greatly reduced according to the first embodiment, the whole manufacturing time can be decreased, and the test cost can be lowered.

Hereinafter, a method for manufacturing a semiconductor memory device according to a second embodiment will be described.

A semiconductor memory device manufactured through the method according to the second embodiment employs components similar to those of the semiconductor memory device manufactured through the method according to the first embodiment. Therefore, repeated details will be omitted in order to avoid redundancy.

According to the method for manufacturing the semiconductor memory device of the second embodiment, a line critical dimension (CD) is increased when forming an active layer, thereby minimizing the influence of stress exerted on the active layer.

FIG. 6 is a view schematically showing the line CD in the semiconductor memory device manufactured through the method according to the second embodiment and the semiconductor memory device manufactured according to the POR.

Two semiconductor wafers E and F shown in FIG. 6 are manufactured using the same semiconductor processes. The semiconductor wafer E represents a wafer for the semiconductor memory device according to the second embodiment.

The semiconductor wafer F represents a wafer for the semiconductor memory device manufactured according to the POR.

During the manufacturing process of the semiconductor wafers E and F, the lithography process performed to form (i.e. define) the active layer is modified for semiconductor wafer E. In particular, the line CD of the active layer for the wafer manufactured according to the second embodiment is increased by an amount as compared with the line CD of the active layer according to the conventional POR. The active areas are measured to determine whether the line CD is realized in the wafer as intended by the user. FIG. 6 illustrates a plot of the measurements for the wafers E and F.

The subject lithography process is performed before the gap-fill process of the trench to form the isolation layer 26 is carried out. The increment (e.g. the increased amount) of the line CD in this lithography process for the semiconductor memory device manufactured according to the second embodiment may be determined within the range of a process capability not to cause gap-fill void, for example, the range of about 3 nm to about 6 nm.

It can be recognized from FIG. 6 that the line CD in the active layer of the semiconductor wafer E becomes about 0.153 μm, which is increased by about 3 nm as compared with the line CD of about 0.15 μm in the active layer of the semiconductor wafer F.

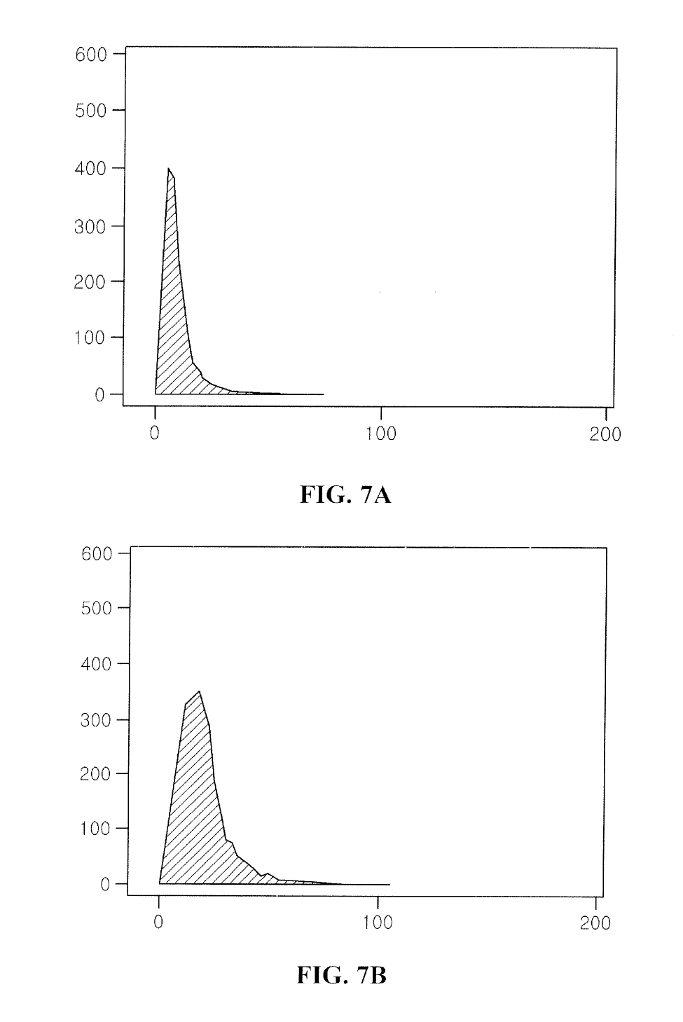

FIGS. 7A and 7B are graphs showing an amount of a bit line leakage current in the semiconductor memory device manufactured through the method according to the second embodiment and the semiconductor memory device manufactured according to the POR. In this case, a voltage has been applied to each semiconductor memory device so as to erase data from bit cells before a leakage current is measured.

In FIGS. 7A and 7B, the semiconductor memory device according to the POR corresponds to the semiconductor wafer F of FIG. 6, and the semiconductor memory device manufactured through the method according to the second embodiment corresponds to the semiconductor water E of FIG. 6.

For reference, 90 nm NOR flash memory products are employed as the semiconductor memory devices of FIGS. 7A and 7B.

FIG. 7A is a graph representing the measured result of a bit line leakage current of the semiconductor memory device manufactured through the method according to the second embodiment, and FIG. 7B is a graph representing the measured result of a bit line leakage current of the semiconductor memory device manufactured according to the POR.

In the graphs of FIGS. 7A and 7B, the X and Y axes represent an amount (μA) of the bit line leakage current and the number of bit lines, respectively.

After a lithography process has been performed while increasing the line CD in the active layer by about 3 nm, an average amount of the bit line leakage current is about 8.9 μA, and the maximum amount of the bit line leakage current is about 74.8 μA as shown in FIG. 7A.

As shown in FIG. 7B, an average amount of the bit line leakage current is about 15.7 μA, and the maximum amount of the bit line leakage current is about 108.7 μA.

As described above, in the semiconductor memory device manufactured through the method according to the second embodiment, the bit line leakage current is reduced by the level of ½ when comparing with that of the POR. This means that the stress resistance of a device is significantly improved in each semiconductor area, especially, an active layer.

As described above, although the methods for manufacturing a semiconductor memory device according to the first and second embodiments are separately described, the first and second embodiments are applicable in a single manufacturing process.

The methods for manufacturing the semiconductor memory device according to the embodiments can have one or more of the following effects.

First, the stress on the active layer can be attenuated regardless of various process conditions, device integration, and device location on a wafer, thereby minimizing, the bit line leakage current.

Second, since an amount of the leakage current generated in bit lines of the semiconductor memory device can be minimized the semiconductor memory device can be reliably operated, and the product yield can be improved.

Any reference in this specification to “one embodiment,” “an embodiment,” “example embodiment,” etc. means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor memory device, the method comprising:
forming a trench for an isolation layer;
performing an annealing process to reduce an amount of a leakage current in an active layer; and
performing a gap-fill process with respect to the trench after performing the annealing process.

2. The method of claim 1, wherein the annealing process satisfies at least one of a first condition to use a nitrogen (N₂) gas, a second condition to perform the annealing process for about 5 minutes to about 15 minutes and a third condition to perform the annealing process under a temperature of about 1100° C. to about 1200° C.

3. The method of claim 1, wherein the forming of the trench comprises:
forming a photoresist pattern to define an area for the isolation layer on a semiconductor substrate,
forming the trench by using the photoresist pattern as an etch mask; and
removing the photoresist pattern.

4. The method of claim 1, wherein the performing of the gap-fill process comprises:
forming an insulating layer on a semiconductor substrate such that the insulating layer fills in the trench; and
forming the isolation layer by planarizing the insulating layer until the semiconductor substrate is exposed.

5. The method of claim 1, wherein an additional annealing process is not performed after the gap-fill process.

6. The method of claim 1, wherein the semiconductor memory device includes a NOR flash memory device

7. A method for manufacturing a semiconductor memory device, the method comprising:
performing a lithography process to define an active layer on a substrate,
wherein a line critical dimension (CD) for the active layer is increased by about 3 nm to about 6 nm as compared with a line CD in a Process of Record (POR).

8. The method of claim 7, wherein the line CD in the POR is in a range of about 0.10 μm to about 0.20 μm.

9. The method of claim 7, wherein the lithography process is performed before a gap-fill process to form an isolation layer is performed with respect to a trench for forming the isolation layer.

10. The method of claim 7, wherein the semiconductor memory device includes a NOR flash memory device.
